(19) United States
(12) Patent Application Publication
(10) Pub. No.: US 2007/0229316 A1
(43) Pub. Date: Oct. 4, 2007

(54) Apparatus and method for character entry in a portable terminal

(75) Inventors: Young-Soo Park, Yongin-si (KR); Jae-Gwa Lee, Seoul (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics C. Ltd.

(21) Appl. No.: 11/605,357

(22) Filed: Nov. 29, 2006

(30) Foreign Application Priority Data
Mar. 16, 2006 (KR) 2006-0024145

(51) Int. Cl. H03M 11/00

(52) U.S. Cl. 341/22

(57) ABSTRACT

A character entry method and apparatus in a terminal in which characters are grouped into a plurality of character sets and a representative character of each of the character sets is imprinted on a respective key are provided. In the character entry method, when a key imprinted with a representative character is pressed, characters belonging to a character set represented by the representative character are displayed and a character among the displayed characters is marked with a selection indication. When a move key is pressed, the selection indication is moved according to the direction of the move key. When an OK key is pressed, the character marked with the selection indication is entered.

### CROSS-REFERENCE TO RELATED PATENT APPLICATION

This application claims the benefit under 35 U.S.C. § 119(a) to a Korean application entitled “Apparatus and Method for Character Entry in a Portable Terminal”, filed in the Korean Intellectual Property Office on Mar. 16, 2006, and assigned Serial No. 2006-24145, the entire disclosure of which is hereby incorporated by reference.

### BACKGROUND OF THE INVENTION

1. Field of the Invention

The present invention relates to an apparatus and method for entering characters in a portable terminal. More particularly, the present invention relates to a character entry apparatus and method for reducing the number of key presses and the number of wrong entries in a portable terminal.

2. Description of the Related Art

Typically, a small-size portable terminal has a limited number of keys, for example, 10 to 12 keys to enter characters with. For languages having 10 to 12 characters in their alphabet, one character is allocated to each key. However, for languages that have a greater number of characters in their alphabet, one key-to-one character assignment is not possible.

FIG. 1 is a diagram illustrating a keypad in a portable terminal, configured to enter Japanese characters according to a Japanese standard.

Referring to FIG. 1, the Japanese characters of the Japanese alphabet (Hiragana) are arranged in order by groups of five characters for assignment to each key. For example, a group of [symbol] is allocated to a digit “1” key, and a group of [symbol] to a digit “2” key. In this manner, a plurality of characters may be allocated to the other digit keys and each digit key is imprinted with the first character of a corresponding group.

On a keypad with the above Japanese alphabet layout, a user enters text in a multi-tap fashion. For example, to enter a word [symbol] , he presses the digit “2” key twice for entering [symbol] , presses the digit “1” key four times for entering [symbol] , and presses the digit “9” key five times for entering [symbol] . The word [symbol] takes a total of 10 taps.

For most languages, character entry relies on the multi-tap scheme. Because of mapping between a plurality of characters and one key, the multi-tap scheme is not user-friendly and is vulnerable to an incorrect entry. To solve this problem, a single-tap character entry scheme was proposed. For details about the single-tap scheme, see T9 (http//www.T9.com), eZi (http//gcorp.com), itap (http//www.mot.com/lexicus/html/itap.html), and for the Japanese language, POS (http//www.muchy.com), the entire disclosures of each of which are hereby incorporated by reference. In the single-tap scheme, one tap or key press is sufficient for entry of one character. This entry scheme is based on an algorithm which automatically displays a word matching to a combination of input characters after searching a dictionary of a given language.

By way of example for the English language, to enter “boy” by the single-tap scheme, the user presses the digit “1” key having the letters “ABC” imprinted thereon for entering “b”, the digit “6” key for entering “o”, and the digit “9” key for entering “y”. Upon entry of the first character “b”, a given dictionary is searched with “b” used as a search key, and upon entry of the second character “o”, “bo” is used as a search key. Finally, upon entry of the last character “y”, the dictionary is searched using “boy” as a search key. Since “boy” is registered in the dictionary, the user selects “boy”.

3×3×3 character combinations can be created using three keys ABC, MNO and WXY. With the first key press, “ABC” is entered at once, and with the second key press “MNO” is entered at once, thereby displaying the possible combinations of letters in ABC times MNO, such as AM, AN, AO, BM, BN, BO, CM, CN, CO. Here, the desired character combination is “bo”. The system continuously searches the dictionary for the next character entry despite the possibility of there being correct words among the two-character combinations, and finally identifies the desired word. During the process, the character combinations associated with the key presses, which can be used as the beginning of the desired word, for example, “bo”, can be selected and displayed continuously. Then, the dictionary is searched in order to find all of the words, which include “bo” in the beginning of the words, and displays the resulting words. The user can identify and select the desired word among the words that the system speculates and displays.

As described above, the single-tap scheme has recently emerged as a character entry technique for a small-size keypad with a limited number of keys, thereby substituting for the multi-tap scheme. The single-tap scheme pursues the efficiency of character entry through a reduction of the number of key presses and increases the likelihood of accurate character entry.

As previously stated, a plurality of characters are inevitably allocated to a single key in a keypad with a limited number of keys and thus one character is accessed by the multi-tap scheme, despite the shortcomings of a large number of key presses and frequent wrong entry.

On the other hand, while the single-tap scheme is effective in reducing the number of key presses, it requires a dictionary for a given language and updating of the dictionary with newly coined words, new abbreviations, or the like. In practice, it is not possible to include every needed word in a rapidly developing information and communication environment, such as person names, Internet addresses, home addresses, or the like. In addition, for a word not registered in the dictionary, the single-tap scheme must be used in conjunction with the multi-tap scheme. In this context, the one-key-for-one-letter method has its own limitations and increases system load due to a large number of character combinations resulting from a plurality of character entries and the accompanying directional searches.

Accordingly, there is a need for an improved apparatus and method for character entry to substantially solve problems encountered with the multi-tap and single-tap schemes.

### SUMMARY OF THE INVENTION

Exemplary embodiments of the present invention address at least the above problems and/or disadvantages and provide at least the advantages described below. Accordingly, an aspect of the present invention is to provide an apparatus and method for character entry to substantially solve problems encountered with the multi-tap and single-tap schemes.

Another aspect of the present invention is to provide an apparatus and method for character entry to reduce the number of key presses and likelihood of an erroneous entry.

The above aspects are achieved by a providing character entry method and apparatus in a terminal in which characters are grouped into a plurality of character sets and a representative character of each of the character sets is imprinted on a respective key.

According to one aspect of the present invention, in a character entry method in a terminal in which characters are grouped into a plurality of character sets and a representative character of each of the character sets is imprinted on a respective key, when a key imprinted with a representative character is pressed, characters belonging to a character set represented by the representative character are displayed and a character among the displayed characters is marked with a selection indication. When a move key is pressed, the selection indication is moved according to the direction of the move key. When an OK key is pressed, the character marked with the selection indication is entered.

According to another aspect of the present invention, in a character entry apparatus in a portable terminal, a keypad has a plurality of keys wherein characters are grouped into a plurality of character sets and a representative character of each of the character sets is imprinted on a respective key of the plurality of keys. When a key imprinted with a representative character is pressed, a display displays characters belonging to a character set represented by the representative character. When a move key is pressed, a controller moves a selection indication for selecting a character to be entered, and when an OK key is pressed, the controller enters a character marked with the selection indication.

Other aspects, advantages, and salient features of exemplary implementation of the present invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a diagram illustrating a keypad in a portable terminal, configured to enter the Japanese characters according to a Japanese standard;

FIG. 2 is a block diagram illustrating an apparatus for entering characters in a portable terminal according to an exemplary embodiment of the present invention;

FIG. 3 is a flowchart illustrating an operation for entering Japanese characters in the portable terminal according to an exemplary embodiment of the present invention; and

FIGS. 4A to 4D are diagrams illustrating an example of Japanese character entry according to an exemplary embodiment of the present invention.

Throughout the drawings, the same drawing reference numerals will be understood to refer to the same elements, features, and structures.

### DETAILED DESCRIPTION OF EXEMPLARY EMBODIMENTS

The matters defined in the description such as a detailed construction and elements are provided to assist in a comprehensive understanding of the embodiments of the invention and are merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

A description will be made of an exemplary character entry method for a terminal equipped with a keypad having a limited number of keys.

In accordance with an exemplary embodiment of the present invention, the characters of an alphabet of a given language are grouped according to criteria. The criteria can be alphabetical order, phonetic value, character shape, or grammatical characteristics. The criteria are set such that the characters can be grouped with optimal visibility and recognizability to the user. The number of the resulting character groups is, for example, 5 to 12, considering that the keypad typically has 12 keys, 5 to 12 character sets are easily allocated to the keys.

After the grouping, a representative character is selected from the characters of each group. The representative characters are determined according to features of the language, and it is preferred that each character set has no more than three representative characters. Since the representative characters are imprinted on a small key, the visibility and recognizability of the character layout decreases with the number of representative characters on each key. Accordingly, the representative characters are selected, taking into account visibility and recognizability. Subsequently, the representative characters are allocated and imprinted on typically 12 keys on the keypad.

Exemplary embodiments of the present invention are applicable to any language as far as it has a plurality of characters in its alphabet, such as Japanese, Russian, Vietnamese, Hebrew, Arabic, Thai, Chinese, and Korean. However, exemplary embodiments of the present invention are described herein in the context of the Japanese language for purpose of illustration.

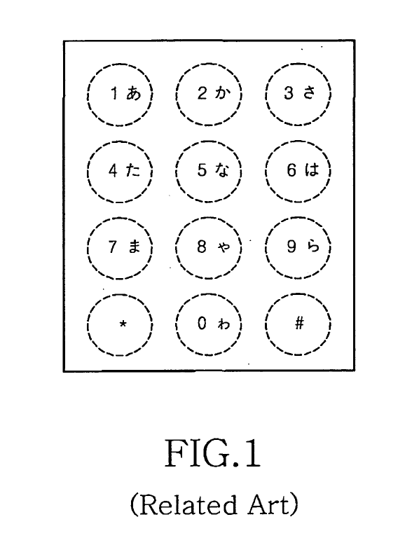

Grouping of the Japanese characters (Hiragana) and selection of representative characters are based on the keypad layout illustrated in FIG. 1, as a virtual Japanese standard. As described earlier, the Japanese alphabets are grouped row by row, for example, the [symbol] row, [symbol] row, and [symbol] row. The first character in each row is a representative of the characters in the character set of the row and is imprinted on a corresponding key.

Table 1 below is a mapping table used for Japanese character entry according to an embodiment of the present invention.

TABLE 1

| Input | Representative |
|---|---|
| character | character |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | |
| [symbol] | |
| [symbol] | [symbol] |
| [symbol] | |
| [symbol] | |
| [symbol] | [symbol] |
| [symbol] | |
| [symbol] | |

As noted from Table 1, the Japanese alphabet is grouped row by row, for example [symbol] row, [symbol] row, and [symbol] row. The first character in each row is a representative character for the character elements in the row.

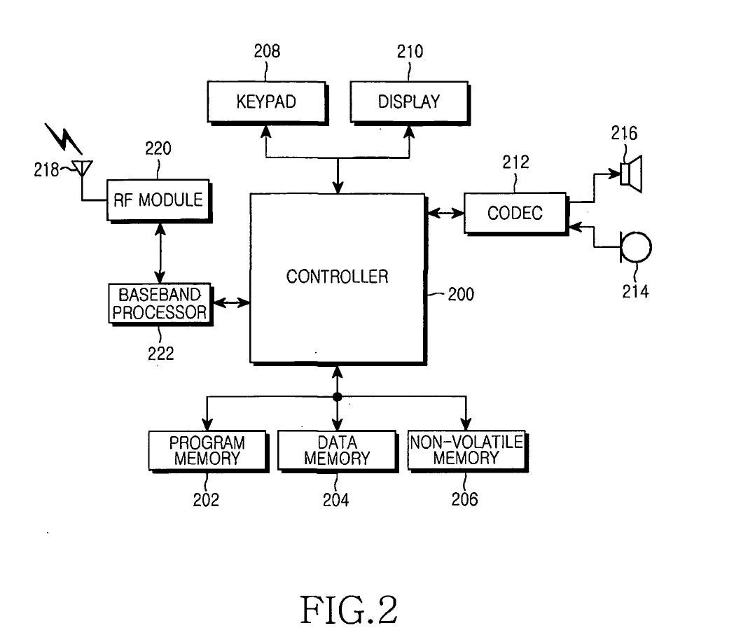

FIG. 2 is a block diagram illustrating an apparatus for entering characters in a portable terminal according to an embodiment of the present invention. The term “portable terminal” includes, but is not limited to, a cellular phone, a Personal Communication System (PCS), a Personal Data Assistant (PDA), an International Mobile Telecommunication-2000 (IMT-2000) terminal, and a 4^{th} generation broadband system terminal. The following description is made of a configuration common to the above terminals.

Referring to FIG. 2, a controller 200 provides overall control to the portable terminal. For example, controller 200 processes and controls the portable terminal for voice calls and data communications. In addition to the conventional functionality, the controller 200 performs a character entry algorithm according to an exemplary embodiment of the present invention.

A memory includes a program memory 202, a data memory 204, and a non-volatile memory 206. The memory stores programs for controlling the overall operation of the terminal, temporary data generated during the operation of the terminal, system parameters, and other data to be kept, such as phone numbers, Short Message Service (SMS) messages, or the like.

A keypad 208 is provided with a 4×3 digit key matrix and a plurality of function keys including Talk, OK, and directional keys. The keypad 208 provides key input data corresponding to a key pressed by the user to the controller 200. According to an exemplary embodiment of the present invention, the digit keys are imprinted with the representative characters of character sets grouped according to a predetermined criterion. As illustrated in FIG. 1, the digit keys 1 to 0 are sequentially imprinted with [symbol] , [symbol] , [symbol] , [symbol] , [symbol] , [symbol] , [symbol] , [symbol] , [symbol] , and [symbol] thereon.

A display 210 displays status information or indicators generated during the operation of the terminal, user-input characters, moving pictures, and still images. The display 210 may be implemented as a touch screen that senses the user's touch. When a key imprinted with a representative character is pressed, characters belonging to a character set represented by the representative character are displayed. The representative character is marked with a selection indication.

An audio Coder-Decoder (CODEC) 212 connected to the controller 200, and a speaker 216 and a microphone 214 connected to the CODEC 212 collectively form a voice input/output portion for voice call.

A Radio Frequency (RF) module 220 processes an RF signal received/transmitted from/to an antenna 218. A baseband processor 222 processes baseband signals transmitted/received between the RF module 220 and the controller 200.

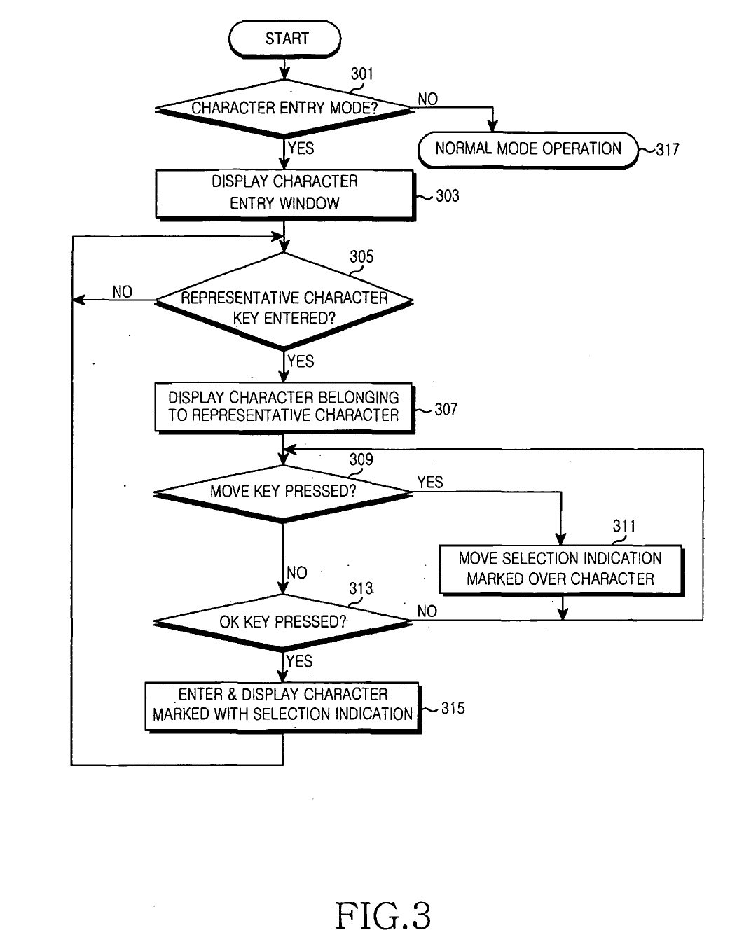

FIG. 3 is a flowchart illustrating an operation for entering Japanese characters in the portable terminal according to an exemplary embodiment of the present invention.

Referring to FIG. 3, the controller 200 monitors a user-selection of character entry mode in step 301. The character entry mode can be any mode requiring character entry such as a message writing mode, a memo mode, and a schedule mode.

If the character entry mode is not selected, the controller 200 performs a normal mode operation, such as an idle mode operation, in step 317.

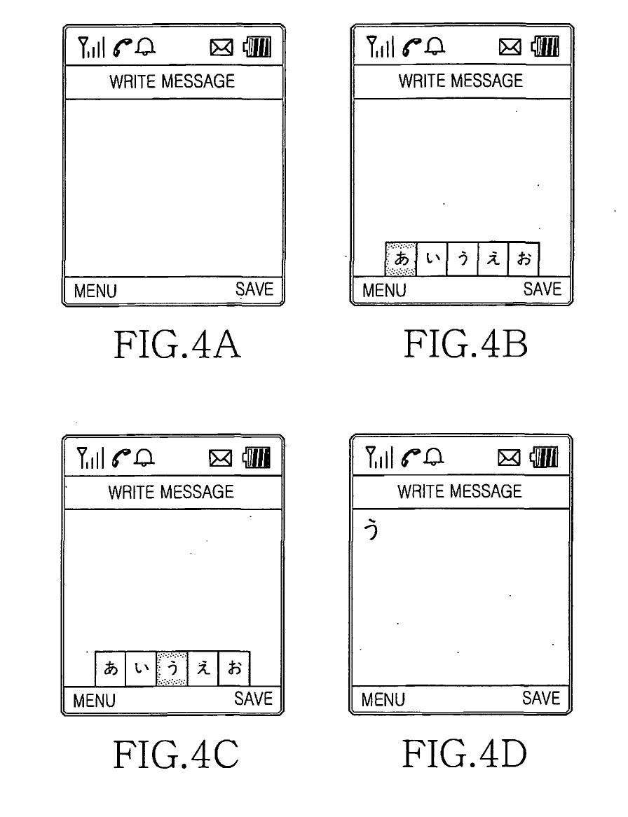

Upon selection of the character entry mode, the controller 200 displays a character entry window on the display 210 in step 303. When a user writes a message, a message entry window is displayed on the display 210 as illustrated in FIG. 4A.

In step 305, the controller 200 monitors the input of a key with a representative character imprinted thereon, hereinafter referred to as a representative character key.

Upon input of the representative character key, the controller 200 displays the characters of a character set that the representative character stands for in step 307. In an exemplary implementation, the characters of a character set that the representative character stands are displayed at the lower part of the screen. In the illustrated case of FIG. 4A, upon input of the representative character key [symbol] , the controller 200 displays the characters [symbol] belonging to a character set represented by the representative character [symbol] on a popup window at a lower part of the screen. For selecting the character, a selection indication is marked over the representative character. The selection indication may be implemented by shading, underlining, flashing, balloon marking, magnification, and the like.

After displaying the character elements represented by the representative character, the controller 200 monitors input of the move character key in step 309. An example that a directional key ( [symbol] / [symbol] ) is designated as the move key will be described. Alternately, a scroll wheel or any other suitable input device may be used.

Upon input of the move key, the controller 200 moves the selection indication over a character according to the direction of the move key. For example, upon input of a right directional key ( [symbol] ) twice when the selection indication is positioned at a character [symbol] as illustrated in FIG. 4B, the controller 200 moves the selection indication over a character [symbol] in step 311 as illustrated in FIG. 4C. Then the controller 200 returns to step 309 to monitor input of the move key.

On the other hand, if the move key has not been pressed, the controller 200 monitors input of an OK key in step 313.

If the OK key has not been pressed, the controller 200 returns to step 309 to monitor input of the move key.

Upon input of the OK key, the controller 200 displays a character marked with the selection indication on the display 210 in step 315. For example, upon input of the OK key with the selection indication over [symbol] as illustrated in FIG. 4C, the controller 200 moves the selection indication over a character [symbol] on the display 210 as illustrated in FIG. 4D.

As noted from Table 1, characters grouped according to a predetermined criterion are entered by the move key and the OK key. For example, to enter a word [symbol] , the digit “6” key imprinted with the representative character [symbol] of the character [symbol] is pressed and the character elements [symbol] under [symbol] are displayed at the lower part of the screen. In this state, the user enters [symbol] by pressing the right directional key ( [symbol] ) four times. Subsequently, the digit “0” key imprinted with the representative character [symbol] of the character [symbol] is pressed and the character elements [symbol] under [symbol] are displayed at the lower part of the screen. Then the user presses the right directional key ( [symbol] ) once and presses the OK key, thereby entering [symbol] .

As described above, certain exemplary embodiments of the present invention perform an efficient entry of grouped characters by pressing a move key and an OK key and advantageously reduces wrong entries. Since the exemplary embodiments of the present invention reduces the need for a dictionary database and a dictionary search algorithm required for the conventional single-tape scheme, exemplary implementations can be simpler and system load can be decreased.

Exemplary embodiments of the present invention can also comprise computer readable codes on a computer readable medium. The computer readable medium can comprise any data storage device that can store data that can be read by a computer system. Examples of a computer readable medium include magnetic storage media (such as, ROM, floppy disks, hard disks, among others), optical recording media (such as, CD-ROMs, or DVDs), and storage mechanisms such as carrier waves (such as, transmission through the Internet). The computer readable medium can also be distributed over network coupled computer systems so that the computer readable code is stored and executed in a distributed fashion. Also, functional programs, codes, and code segments for accomplishing exemplary embodiments of the present invention can be construed by programmers of ordinary skill in the art to which the present invention pertains.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A character entry method in a terminal, the method comprising:
displaying, when a key comprising a representative character is pressed, characters belonging to a character set represented by the representative character and marking a character among the displayed characters with a selection indication;
moving, when a move key is pressed, the selection indication according to a direction of the key; and
entering, when an OK key is pressed, the character marked with the selection indication.

2. The character entry method of claim 1, wherein the selection indication is marked over the representative character when the characters are displayed.

3. The character entry method of claim 1, wherein the selection indication comprises at least one of shading, underlining, flashing, and magnification.

4. The character entry method of claim 1, further comprising displaying the entered character on a main screen.

5. A character entry apparatus in a portable terminal, comprising:
a keypad having a plurality of keys wherein characters are grouped into a plurality of character sets and a respective key of the plurality of keys comprises a representative character of each of the character sets;
a display for, when a key with a representative character is pressed, displaying characters belonging to a character set represented by the representative character; and
a controller for when a move key is pressed, moving a selection indication for selecting a character to be entered, when a confirmation key is pressed, entering a character with the selection indication.

6. The character entry apparatus of claim 5, wherein the confirmation key comprises an OK key.

7. The character entry apparatus of claim 5, wherein the move key comprises a scroll wheel.

8. The character entry apparatus of claim 6, wherein the OK key comprises at least one of a separate key and a scroll wheel (pressed).

9. The character entry apparatus of claim 5, wherein the selection indication is marked over the representative character when the characters are displayed.

10. The character entry apparatus of claim 5, wherein the selection indication comprises at least one of shading, underlining, flashing, and magnification.

11. A computer-readable recording medium having recorded thereon a program for character entry for a terminal, comprising a plurality of keys wherein characters are grouped into a plurality of character sets and a respective key of the plurality of keys comprises a representative character of each of the character sets, comprising:
a first code segment, displaying, when a key comprising a representative character is pressed, characters belonging to a character set represented by the representative character and marking a character among the displayed characters with a selection indication;
a second code segment, for moving, when a move key is pressed, the selection indication according to a direction of the key; and;
a third code segment, for entering, when an OK key is pressed, the character marked with the selection indication.

12. The computer-readable recording medium of claim 11, wherein the selection indication is marked over the representative character when the characters are displayed.

13. The computer-readable recording medium of claim 11, wherein the selection indication comprises at least one of shading, underlining, flashing, and magnification.

14. The computer-readable recording medium of claim 11, further comprising displaying the entered character on a main screen.
